(19) United States
(12) Patent Application Publication
(10) Pub. No.: US 2025/0240976 A1
(43) Pub. Date: Jul. 24, 2025

(54) CROSS-POINT MEMORY CELL AND METHOD

(71) Applicant: TAIWAN SEMICONDUCTOR MANUFACTURING COMPANY, LTD., Hsinchu (TW)

(72) Inventors: Jui-Jen WU, Hsinchu (TW); Jen-Chieh LIU, Hsinchu (TW); Yi-Lun LU, Hsinchu (TW); Win-San KHWA, Hsinchu (TW); Meng-Fan CHANG, Hsinchu (TW)

(21) Appl. No.: 18/733,284

(22) Filed: Jun. 4, 2024

Related U.S. Application Data
(60) Provisional application No. 63/622,373, filed on Jan. 18, 2024.

(51) Int. Cl. H10B 63/00; G11C 5/06; G11C 13/00; H01L 23/522; H01L 23/528

(52) U.S. Cl. CPC H10B 63/34; G11C 5/063; G11C 13/0026; G11C 13/0028; H01L 23/5226; H01L 23/5283; H01L 23/5286

(57) ABSTRACT

An IC device includes first and second transistors and a memory device. The first transistor includes a first source/drain (S/D) terminal coupled to a first select line, a second S/D terminal, and a gate coupled to a first word line. The second transistor includes a first S/D terminal coupled to a first bit line, a second S/D terminal, and a gate. The memory device is coupled to the second S/D terminal of the second transistor, and a first storage node includes the second S/D terminal of the first transistor and the gate of the second transistor.

### PRIORITY CLAIM

The present application claims the priority of U.S. Provisional Application No. 63/622,373, filed Jan. 18, 2024, which is incorporated herein by reference in its entirety.

### BACKGROUND

In many applications, integrated circuits (ICs) include memory circuits that store data used by other circuit components, e.g., logic, processor, or computational circuits. Memory circuits can include volatile memory such as dynamic random-access memory (DRAM) in which data retention relies on the IC being powered on, and in some cases, the stored data being periodically refreshed. Memory circuits can also include non-volatile memory (NVM) such as resistive RAM (RRAM) in which data are retained during periods when the IC is powered off.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory circuit, in accordance with some embodiments.

FIGS. 2A and 2B are schematic diagrams of memory cells, in accordance with some embodiments.

FIGS. 3A and 3B are schematic diagrams of memory cells, in accordance with some embodiments.

FIG. 4 is a cross-sectional view of an IC device, in accordance with some embodiments.

FIG. 5 is a cross-sectional view of an IC device, in accordance with some embodiments.

FIGS. 6A-6F depict memory circuit operating parameters, in accordance with some embodiments.

FIG. 7 is a flowchart of a method of operating a memory circuit, in accordance with some embodiments.

FIG. 8 is a flowchart of a method of manufacturing a memory circuit, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a memory cell and method include first and second transistors, a memory device coupled to a first source/drain (S/D) terminal of the second transistor, and a storage node including a first S/D terminal of the first transistor and gate of the second transistor. A second S/D terminal and gate of the first transistor are coupled to respective select and word lines, and a second S/D terminal of the second transistor is coupled to a bit line. The memory cell is thereby capable of being used in a memory circuit in which a combination of word line and select signals are used to uniquely couple a selected memory device to a corresponding bit line such that half-selected memory cell disturb conditions are avoided.

By avoiding half-selected disturb conditions, power consumption during write operations is reduced compared to approaches in which data are rewritten to address half-selected disturb conditions resulting from coupling non-selected memory devices to bit lines, e.g., by selecting memory cells using only word line signals.

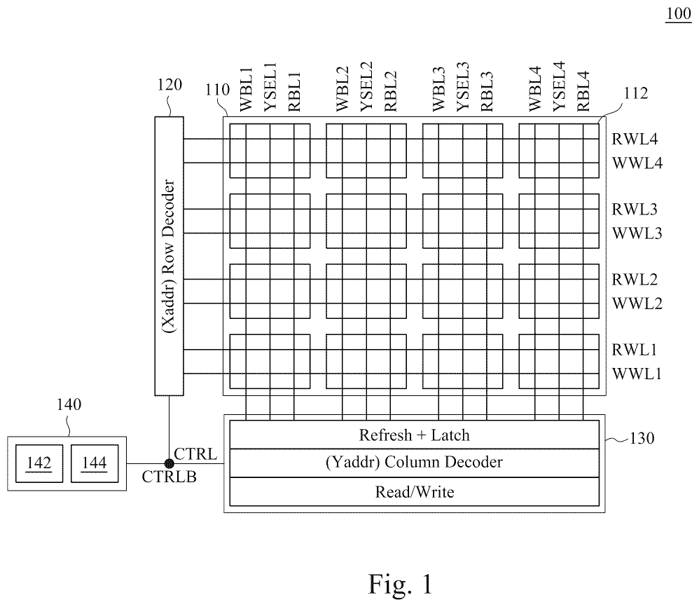

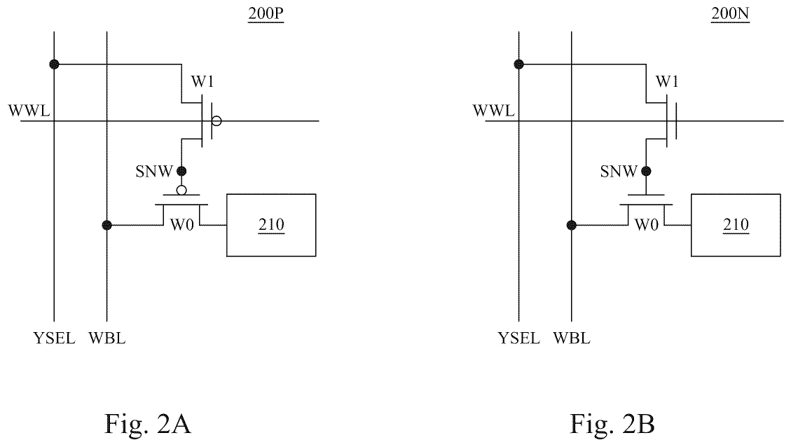

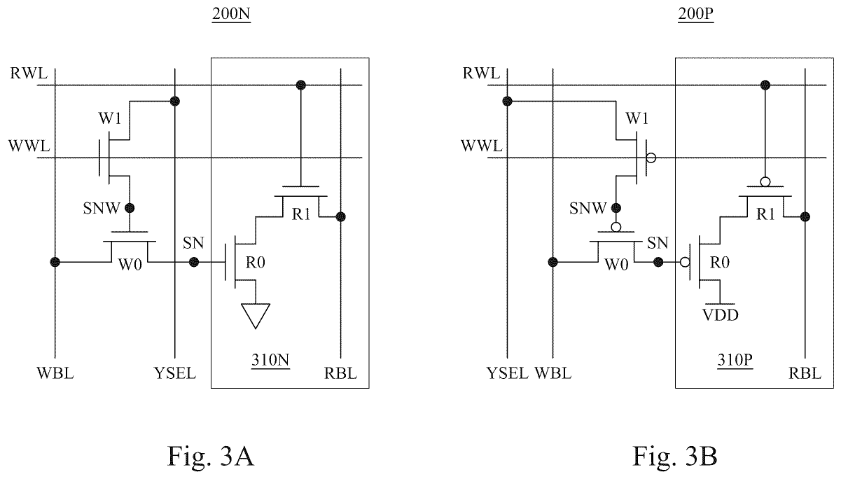

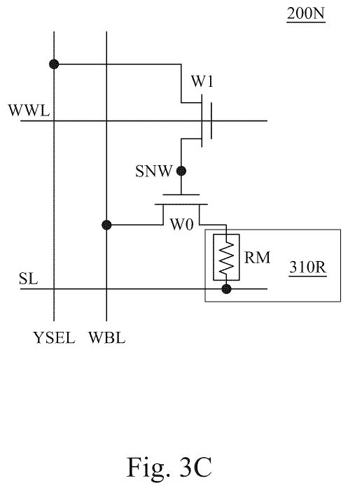

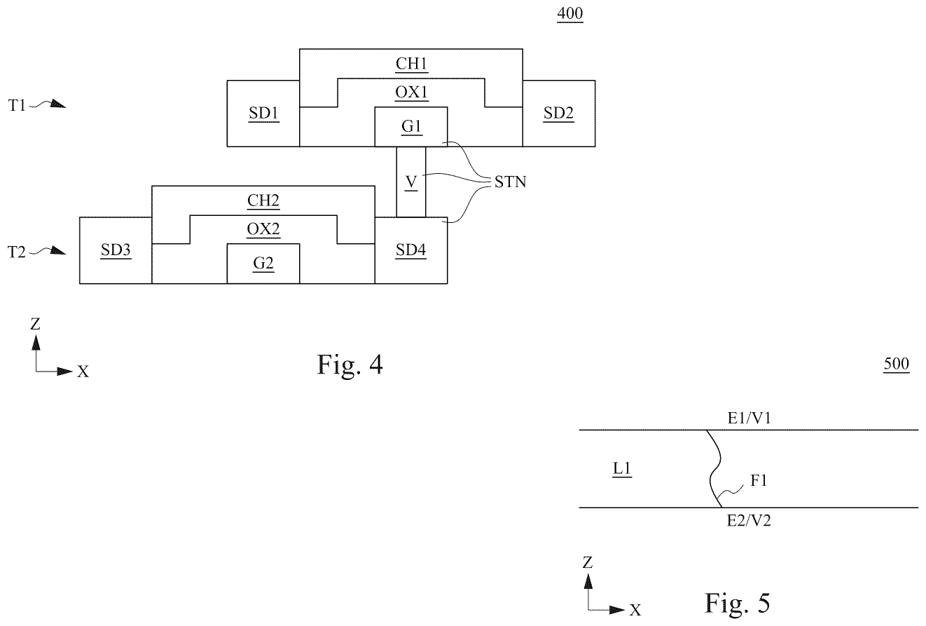

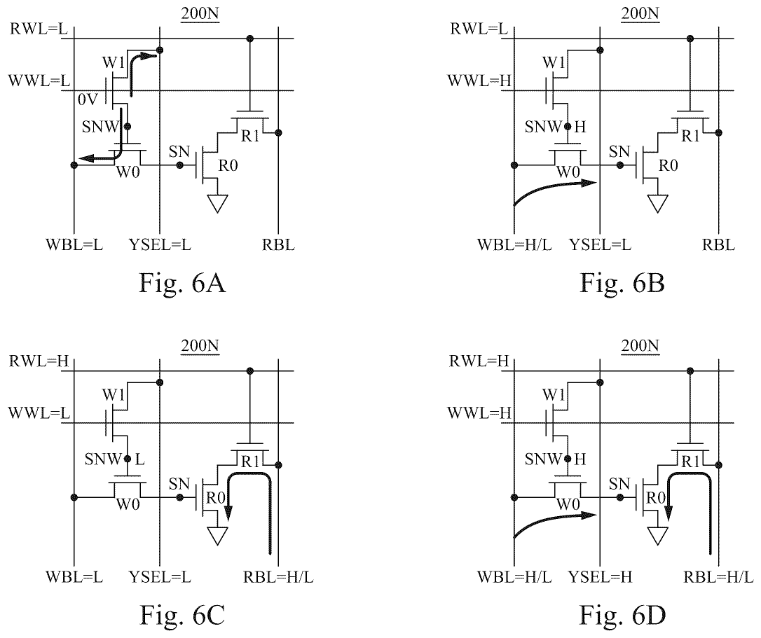

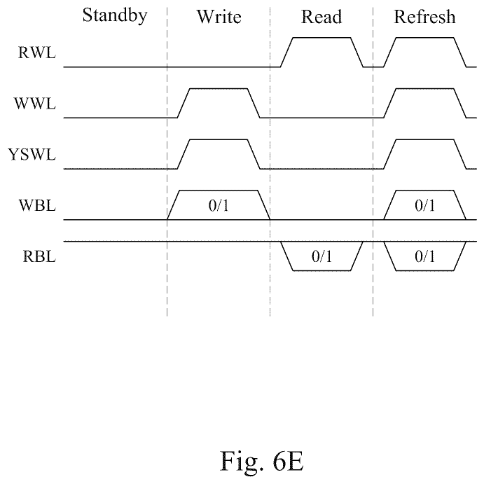

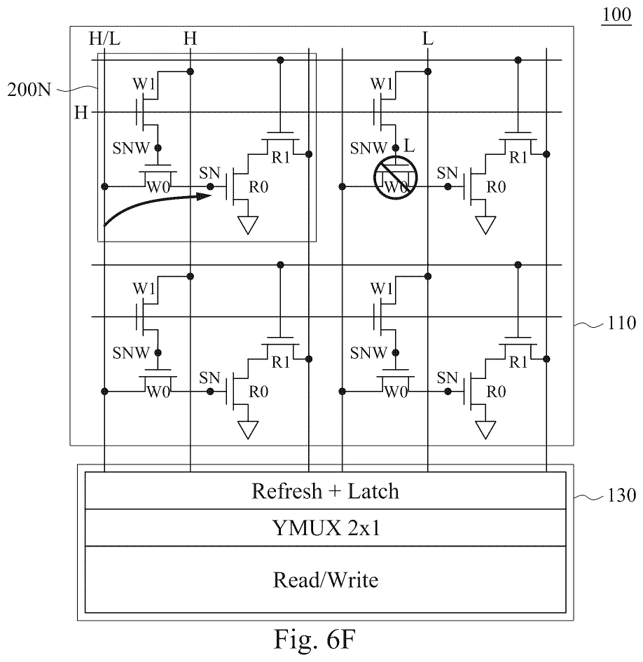

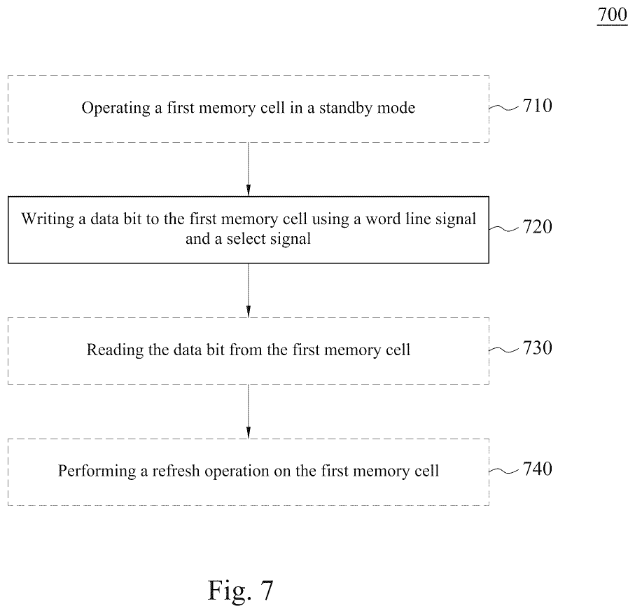

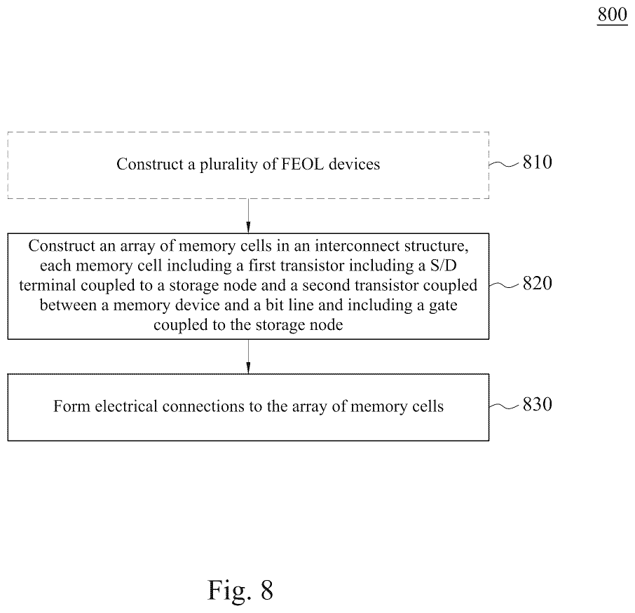

In accordance with various embodiments, FIG. 1 is a schematic diagram of a memory circuit 100, FIGS. 2A-3C are schematic diagrams of memory cells 200N and 200P usable in memory circuit 100, FIGS. 4 and 5 are cross-sectional views of IC devices 400 and 500 usable in memory cells 200N and 200P, FIGS. 6A-6F depict non-limiting examples of memory circuit 100 operating parameters, FIG. 7 is a flowchart of a method 700 of operating a memory circuit, and FIG. 8 is a flowchart of a method 800 of manufacturing a memory circuit.

In some embodiments, memory circuit 100 is some or all of an integrated circuit (IC). In some embodiments, memory circuit 100 is included in another IC circuit and/or package, e.g., a digital circuit, an analog circuit, a compute in memory (CIM) circuit, a near memory computing (NMC) circuit positioned in a fan-out, 3D, 2.5D, or other IC package, and/or other suitable circuit.

FIGS. 1-6F are simplified for the purpose of illustration. In some embodiments, one or more of memory circuit 100, memory cells 200N or 200P, or IC devices 400 or 500 includes features in addition to those depicted in FIGS. 1-6F, e.g., a global control and/or input/output (I/O) circuit configured to generate one or more signals including and/or in addition to those discussed below. Some circuit elements depicted in FIGS. 1-6F include corresponding input and/or output terminals that are not labeled for the purpose of clarity.

FIG. 1 is a diagram of memory circuit 100, in accordance with some embodiments. Memory circuit 100 includes an array 110 of memory cells 112 coupled to a word line driver 120 and a read/write (R/W) interface 130, and a control circuit 140 coupled to word line driver 120 and R/W interface 130 through a control signal bus CTRLB. Memory circuit 100 is configured to be capable of executing some or all of a method, e.g., method 700 discussed below with respect to FIG. 7, in which data are written to and/or read from one or more instances of memory cell 112, as discussed below.

Two or more circuit elements are considered to be coupled based on one or more direct signal connections and/or one or more indirect signal connections that include one or more logic devices, e.g., an inverter or logic gate, between the two or more circuit elements. In some embodiments, signal communications between the two or more coupled circuit elements are capable of being modified, e.g., inverted or made conditional, by the one or more logic devices.

In the embodiment depicted in FIG. 1, memory circuit 100 is configured as a dynamic random-access memory (DRAM) circuit including memory cells 112 configured as DRAM cells in which stored data are refreshed over time, e.g., periodically. In some embodiments, memory circuit 100 is otherwise configured as a memory circuit, e.g., as a non-volatile memory (NVM) circuit including memory cells 112 configured as NVM cells.

Array 110 includes memory cells 112 (a single instance labeled for clarity) arranged in rows and columns (not labeled). Each memory cell 112 of each row of memory cells 112 is coupled to one each of word lines WWL1-WWL4 and word lines RWL1-RWL4, and each memory cell 112 of each column of memory cells 112 is coupled to one each of bit lines WBL1-WBL4, bit lines RBL1-RBL4, and select lines YSEL1-YSEL4.

For clarity, in addition to the corresponding word, bit, and select lines, reference designators WWL1-WWL4 and RWL1-RWL4 also represent word line signals, reference designators WBL1-WBL4 and RBL1-RBL4 also represent bit line signals, and reference designators YSEL1-YSEL4 also represent select signals, each discussed below.

In the embodiment depicted in FIG. 1, array 110 includes total numbers of rows and columns equal to four for the purpose of illustration. In various embodiments, array 110 includes total numbers of rows and/or columns fewer or greater than four.

In the embodiment depicted in FIG. 1, array 110 includes the rows and columns arranged along respective row and column dimensions (not labeled). In some embodiments, array 110 has a three-dimensional (3D) arrangement, also referred to as a stacked arrangement, that includes one or more array layers (not shown) arranged perpendicularly to the row and column dimensions of the single layer depicted in FIG. 1 such that array 110 includes rows and columns in addition to those depicted in FIG. 1.

In the embodiment depicted in FIG. 1, each memory cell 112 is a five-terminal device including terminals coupled to corresponding ones of word lines WWL1-WWL4, word lines RWL1-RWL4, bit lines WBL1-WBL4, bit lines RBL1-RBL4, and select lines YSEL1-YSEL4. Each memory cell 112 corresponds to one of memory cells 200N or 200P, discussed below with respect to FIGS. 2A-5.

In some embodiments, e.g., as discussed below with respect to FIG. 3C, memory circuit 100 does not include one or both of word lines RWL1-RWL4 or bit lines RBL1-RBL4, and each memory cell 112 is a four-terminal device including terminals coupled to corresponding ones of word lines WWL1-WWL4, bit lines WBL1-WBL4, and select lines YSEL1-YSEL4.

By the configurations discussed below, each memory cell 112 includes a memory device (not shown in FIG. 1), e.g., a memory device 210 discussed below, and is configured to, during write operations, couple the memory device to the corresponding bit line WBL1-WBL4 responsive to a combination of a word line signal received from the corresponding word line WWL1-WWL4 and a select signal received from the corresponding select line YSEL1-YSEL4. In some embodiments, memory cells 112 are referred to as cross-point memory cells 112.

Word line driver 120, also referred to as row decoder 120 or multiplexer 120 in some embodiments, is an electronic circuit configured to output word line signals WWL1-WWL4 and RWL1-RWL4 on respective word lines WWL1-WWL4 and RWL1-RWL4, also referred to as write word lines WWL1-WWL4 and read word lines RWL1-RWL4 in some embodiments, responsive to one or more of control signals CTRL received from control circuit 140 on control signal bus CTRLB and/or from one or more circuits (not shown) external to memory circuit 100.

In some embodiments, a signal, e.g., a control signal CTRL or word line signal, is a time-based series of transitions between high and low voltage levels, e.g., corresponding to high and low logic levels. A high voltage or logic level corresponds to a voltage within a predefined range of a power supply voltage level, e.g., a VDD voltage level, and a low voltage or logic level corresponds to a voltage within a predefined range of a reference voltage level, e.g., a VSS or ground voltage level.

In write operations, word line driver 120 is configured to, responsive to one or more of control signals CTRL, output a word line signal WWL1-WWL4, also referred to as a word line write signal WWL1-WWL4 in some embodiments, on a corresponding one of word lines WWL1-WWL4, e.g., corresponding to a row address Xaddr, including one of the high or low logic levels. Each memory cell 112 coupled to the one of word lines WWL1-WWL4 is configured to couple the memory device to the corresponding one of bit lines WBL1-WBL4 in response to the word line signal WWL1-WWL4 having the one of the high or low logic levels, and further in response to a corresponding select signal YSEL1-YSEL4 as discussed below.

Word line driver 120 is thereby configured to output word line signals WWL1-WWL4 on word lines WWL1-WWL4 configured to cause, in part, each memory cell 112 to couple an included memory device to a corresponding one of bit lines WBL1-WBL4.

In read operations, in the embodiment depicted in FIG. 1, word line driver 120 is configured to, responsive to one or more of control signals CTRL, output a word line signal RWL1-RWL4, also referred to as a word line read signal RWL1-RWL4 in some embodiments, on a corresponding one of word lines RWL1-RWL4, e.g., corresponding to row address Xaddr, including one of the high or low logic levels. Each memory cell 112 coupled to the one of word lines RWL1-RWL4 is configured to couple the memory device to the corresponding one of bit lines RBL1-RBL4 in response to the word line signal RWL1-RWL4 having the one of the high or low logic levels. In some embodiments, each memory cell 112 is configured to couple the memory device to the corresponding one of bit lines RBL1-RBL4 solely in response to the corresponding word line signal RWL1-RWL4.

In some embodiments, e.g., those in which each memory cell 112 is a four-terminal device, in read operations, word line driver 120 is configured to, responsive to one or more of control signals CTRL, output the word line read signal RWL1-RWL4 on the corresponding one of word lines WWL1-WWL4, and each memory cell 112 coupled to the one of word lines WWL1-WWL4 is configured to couple the memory device to the corresponding one of bit lines WBL1-WBL4 in response to the word line signal RWL1-RWL4 having the one of the high or low logic levels.

R/W interface 130, also referred to as local I/O circuit 130 in some embodiments, is an electronic circuit configured to output select signals YSEL1-YSEL4 on select lines YSEL1-YSEL4, also referred to as write-select signals YSEL1-YSEL4 and write-select lines YSEL1-YSEL4 in some embodiments, responsive to one or more of control signals CTRL received from control circuit 140 on control signal bus CTRLB and/or from one or more circuits (not shown) external to memory circuit 100.

In write operations, R/W interface 130 is configured to, responsive to one or more of control signals CTRL, output a select signal YSEL1-YSEL4 on a corresponding one of select lines YSEL1-YSEL4, e.g., corresponding to a column address Yaddr, including one of the high or low logic levels. Each memory cell 112 coupled to the one of select lines YSEL1-YSEL4 is configured to couple the memory device to the corresponding one of bit lines WBL1-WBL4 in response to the select signal YSEL1-YSEL4 having the one of the high or low logic levels, and further in response to the corresponding word line signal WWL1-WWL4 as discussed above.

R/W interface 130 is thereby configured to output the select signals YSEL1-YSEL4 on select lines YSEL1-YSEL4 configured to cause, in part, each memory cell 112 to couple an included memory device to a corresponding one of bit lines WBL1-WBL4.

In write operations, R/W interface 130 is also configured to, responsive to one or more of control signals CTRL, output a bit line signal WBL1-WBL4, also referred to as one or more programming voltages in some embodiments, on a corresponding one of bit lines WBL1-WBL4, e.g., corresponding to column address Yaddr, including one of the high or low logic levels or one or more other voltage levels configured to program the corresponding memory cell 112 to a state corresponding to a high or low logic level.

In read operations, R/W interface 130 is also configured to, responsive to one or more of control signals CTRL, output a bit line signal RBL1-RBL4, also referred to as one or more read or bias voltages in some embodiments, on a corresponding one of bit lines RBL1-RBL4, e.g., corresponding to column address Yaddr, including one of the high or low logic levels or one or more other voltage levels configured to bias the corresponding memory cell 112 to a level corresponding to a read operation of R/W interface 130, e.g., a current sensing operation.

In some embodiments, e.g., those in which each memory cell 112 is a four-terminal device, in read operations, R/W interface 130 is configured to, responsive to one or more of control signals CTRL, output the bit line signal RBL1-RBL4 on the corresponding one of bit lines WBL1-WBL4, and each memory cell 112 is thereby biased to the one of the high or low logic levels or one or more other voltage levels received from the corresponding one of bit lines WBL1-WBL4. In some embodiments, a fourth terminal of each memory cell 112 is coupled to a signal line (not shown in FIG. 1), e.g., a source line, configured to have a reference voltage level such as ground and/or coupled to a signal detection circuit of R/W interface 130.

In the embodiment depicted in FIG. 1 in which memory circuit 100 is configured as a DRAM circuit including memory cells 112 configured as DRAM cells, R/W interface 130 includes a refresh and latch circuit, a column decoder, e.g., a multiplexer, and a read/write circuit. The refresh and latch circuit is configured to perform refresh operations by reading, latching, and rewriting data from and to memory cells 112, e.g., periodically, the column decoder is configured to output select signals YSEL1-YSEL4 and activate bit lines WBL1-WBL4 and/or RBL1-RBL4 responsive to address Yaddr, and the read/write circuit is configured to output data to, and read data from, memory cells 112 selected in accordance with select signals YSEL1-YSEL4 and the activated bit lines WBL1-WBL4 and/or RBL1-RBL4, each responsive to one or more of control signals CTRL.

In some embodiments, R/W interface 130 includes one or more signal detection circuits (not shown), e.g., sense amplifiers, and is thereby configured to perform one or more read operations, e.g., measure one or more currents, voltages, or voltage differences, based on one or more signals received on one or a combination of bit lines RBL1-RBL4 and/or WBL1-WBL4, in which a programmed logic high or logic low level of a selected memory cell 112 is detected.

In some embodiments, the one or more signal detection circuits are configured to determine a programmed state of a selected memory cell 112 based on a first threshold voltage level being greater or less than a second threshold voltage level. In some embodiments, the one or more signal detection circuits are configured to determine the programmed state of the selected memory cell 112 based on one or more currents, e.g., a channel current, corresponding to one or more values of bit line signal RBL1-RBL4 in combination with a voltage level stored on a storage node of the corresponding memory device, e.g., a storage node SN of a storage device 310N or 310P discussed below with respect to FIGS. 3A and 3B.

Control circuit 140 is an electronic circuit configured to control operation of memory circuit 100 by generating the one or more control signals CTRL on control signal bus CTRLB and received by word line driver 120 and R/W interface 130 in accordance with the embodiments discussed herein. In various embodiments, control circuit 140 includes a hardware processor 142 and a non-transitory, computer-readable storage medium 144. Storage medium 144, amongst other things, is encoded with, i.e., stores, computer program code, i.e., a set of executable instructions. Execution of the instructions by hardware processor 142 represents (at least in part) a memory circuit operation tool which implements a portion or all of, e.g., method 700 discussed below with respect to FIG. 7 (hereinafter, the noted processes and/or methods).

Processor 142 is electrically coupled to non-transitory, computer-readable storage medium 144, an I/O interface, and a network via a bus (details not shown). The network interface is connected to a network (not shown) so that processor 142 and non-transitory, computer-readable storage medium 144 are capable of connecting to external elements via the network. Processor 142 is configured to execute the computer program code encoded in non-transitory, computer-readable storage medium 144 in order to cause control circuit 140 and memory circuit 100 to be usable for performing a portion or all of the noted processes and/or methods. In one or more embodiments, processor 142 is a central processing unit (CPU), a multi-processor, a distributed processing system, an application specific integrated circuit (ASIC), and/or a suitable processing unit.

In one or more embodiments, non-transitory, computer-readable storage medium 144 is an electronic, magnetic, optical, electromagnetic, infrared, and/or a semiconductor system (or apparatus or device). For example, non-transitory, computer-readable storage medium 144 includes a semiconductor or solid-state memory, a magnetic tape, a removable computer diskette, a random-access memory (RAM), a static RAM (SRAM), a dynamic RAM (DRAM), a read-only memory (ROM), a rigid magnetic disk, and/or an optical disk. In one or more embodiments using optical disks, non-transitory, computer-readable storage medium 144 includes a compact disk-read only memory (CD-ROM), a compact disk-read/write (CD-R/W), and/or a digital video disc (DVD).

In one or more embodiments, non-transitory, computer-readable storage medium 144 stores the computer program code configured to cause control circuit 140 to generate the control signals so as to be usable for performing a portion or all of the noted processes and/or methods. In one or more embodiments, non-transitory, computer-readable storage medium 144 also stores information which facilitates performing a portion or all of the noted processes and/or methods. In one or more embodiments, non-transitory, computer-readable storage medium 144 stores one or more data sets, e.g., a plurality of data patterns, discussed below with respect to the noted processed and/or methods.

FIGS. 2A and 2B are schematic diagrams of respective memory cells 200P and 200N, in accordance with some embodiments. Each of memory cells 200P and 200N is usable as memory cell 112 discussed above with respect to FIG. 1.

Each of FIGS. 2A and 2B includes a word line/signal WWL corresponding to one of word lines/signals WWL1-WWL4, a select line/signal YSEL corresponding to one of select lines/signals YSEL1-YSEL4, and a bit line/signal WBL corresponding to one of bit lines/signals WBL1-WBL4, each discussed above with respect to FIG. 1.

Each of memory cells 200P and 200N includes a transistor W1 including a S/D terminal coupled to select line YSEL, a gate coupled to word line WWL, and a S/D terminal coupled to a storage node SNW, and a transistor W0 including a S/D terminal coupled to bit line WBL, a gate coupled to storage node SNW, and a S/D terminal coupled to memory device 210. As depicted in FIGS. 2A and 2B, memory cell 200P includes each of transistors W1 and W0 including a p-type transistor, and memory cell 200N includes each of transistors W1 and W0 including an n-type transistor.

A S/D terminal may refer to a source or a drain, individually or collectively, dependent upon the context.

A storage node, e.g., storage node SNW, is an IC structure including one or more conductive elements, e.g., metal line segments, configured to be selectively coupled to and decoupled from other structure elements through one or more switching devices, e.g., a transistor such as transistor W1. In some embodiments, metal segments of a storage node are included in one or more transistors as one or more S/D terminals and/or one or more gates. In some embodiments, a storage node includes one or more via structures positioned between and electrically connecting multiple metal segments.

In some embodiments, metal segments and via structures, if included, of a storage node are back end of line (BEOL) features positioned in an interconnect structure of an IC. In some embodiments, a storage node is a storage node STN of IC device 400 discussed below with respect to FIG. 4.

In operation, while decoupled from other structure elements by the one or more switching devices, the storage node is electrically isolated by layers of dielectric materials and closed channel(s) of the one or more switching devices such that a sufficiently small leakage current and sufficiently large capacitance, e.g., parasitic capacitance, cause an electrical charge on the storage node to be substantially retained for a retention period. The retention period has a minimum duration based on the storage node configuration and charge levels, and is sufficiently long to allow multiple read and/or write operations to be performed by a circuit, e.g., memory circuit 100, while the charge is being substantially retained on the storage node.

A charge retained on storage node SNW is thereby capable of biasing the gate of transistor W0 such that transistor W0 of a non-selected given memory cell 200P or 200N is capable of being switched off during the retention period as one or more write operations are performed on one or more other (selected) memory cells, as discussed below with respect to FIGS. 6A-6F.

In the embodiments depicted in FIGS. 2A and 2B, storage node SNW retaining a charge corresponding to the high logic level corresponds to the p-type transistor W0 of memory circuit 200P being switched off during the retention period, and storage node SNW retaining a charge corresponding to the low logic level corresponds to the n-type transistor W0 of memory circuit 200N being switched off during the retention period.

As the minimum duration of the retention period increases, the number of read and/or write operations that can be performed on other memory cells increases. In some embodiments, a storage node, e.g., storage node SNW, has a minimum duration ranging from 100 milliseconds (ms) to 10 seconds. In some embodiments, a storage node has a minimum duration ranging from 500 ms to 5 seconds.

Memory device 210 is an electrical, electromechanical, electromagnetic, or other device configured to store a data bit represented by logical states. In some embodiments, a logical state corresponds to a voltage level of an electrical charge stored in memory device 210. In some embodiments, a logical state corresponds to a physical property, e.g., a resistance or magnetic orientation, of a portion or all of memory device 210.

In some embodiments, memory device 210 includes a static random-access memory (SRAM) device, a DRAM device, an embedded DRAM (eDRAM) device, a gain-cell device, a resistive random-access memory (RRAM) device, a magnetoresistive random-access memory (MRAM) device, a ferroelectric random-access memory (FeRAM) device, a NOR or NAND flash device, a conductive-bridging random-access memory (CBRAM) device, an NVM device, a 3D NVM device, or other memory device type capable of storing bit data.

Memory circuit 100 including memory cells 200N or 200P, each including transistors W1 and W0, storage node SNW, and memory device 210, is thereby configured to selectively couple each memory device 210 to a corresponding bit line WBL1-WBL4 responsive to a corresponding combination of a word line signal WWL1-WWL4 and a select signal YSEL1-YSEL4. The memory device 210 of a selected memory cell 200N or 200P is thereby coupled to the corresponding bit line WBL1-WBL4 such that half-selected disturb conditions are avoided on the memory devices 210 of non-selected memory cells 200N or 200P.

By avoiding half-selected disturb conditions, power consumption during write operations in memory circuit 100 is reduced compared to approaches in which data are rewritten to address half-selected disturb conditions resulting from coupling non-selected memory devices to bit lines, e.g., by selecting memory cells using only word line signals.

FIGS. 3A-3C are schematic diagrams of non-limiting examples of memory cells 200N or 200P, in accordance with some embodiments. Each of FIGS. 3A-3C includes word line/signal WWL, select line/signal YSEL, and bit line/signal WBL, each discussed above with respect to FIGS. 2A and 2B. Each of FIGS. 3A and 3B also includes a word line/signal RWL corresponding to one of word lines/signals RWL1-RWL4 and a bit line/signal RBL corresponding to one of bit lines/signals RBL1-RBL4, each discussed above with respect to FIG. 1. FIG. 3C also includes a signal line/signal SL, discussed below.

FIG. 3A depicts memory cell 200N including a memory device 310N usable as memory device 210, FIG. 3B depicts memory cell 200P including a memory device 310P usable as memory device 210, and FIG. 3C depicts memory cell 200N including a memory device 310R usable as memory device 210.

Each of memory devices 310N and 310P includes transistors R1 and R0. Transistor R1 includes a S/D terminal coupled to bit line RBL, a gate coupled to word line RWL, and a S/D terminal coupled to a S/D terminal of transistor R0. Transistor R0 includes a gate coupled to a storage node SN that also includes a S/D terminal of transistor W0, and a S/D terminal coupled to a power distribution path. As depicted in FIGS. 3A and 3B, memory device 310N includes each of transistors R1 and R0 including an n-type transistor and the power distribution path including a ground path, and memory device 310P includes each of transistors R1 and R0 including a p-type transistor and the power distribution path including a power supply distribution path.

Each of memory devices 310N and 310P is thereby configured as a gain-cell device in which a charge retained on storage node SN is capable of representing a logical state based on being greater than or less than a threshold voltage of transistor R0.

In operation, storage node SN of memory device 310N retaining a charge corresponding to the high logic level represents a first logical state corresponding to transistor R0 being switched on, and storage node SN of memory device 310N retaining a charge corresponding to the low logic level represents a second logical state corresponding to transistor R0 being switched off. Storage node SN of memory device 310P retaining a charge corresponding to the low logic level represents the first logical state corresponding to transistor R0 being switched on, and storage node SN of memory device 310P retaining a charge corresponding to the high logic level represents the second logical state corresponding to transistor R0 being switched off.

Memory device 310R includes an RRAM device RM coupled between a S/D terminal of transistor W0 and signal line SL. RRAM device RM is a two-terminal device capable of being programmed, e.g., by one or more differential voltages applied across the two terminals, to at least two resistance levels corresponding to first and second logical states. In some embodiments, RRAM device includes variable resistance device 500 discussed below with respect to FIG. 5.

Signal line SL is an electrical path coupled to a voltage source (not shown), ground, word line driver 120, and/or R/W interface 130 and thereby configured to apply and/or receive signal SL to/from a terminal of RRAM device RM. In some embodiments, signal line/signal SL is one of word lines/signals RWL1-RWL4 or one of bit lines/signals RBL1-RBL4 discussed above.

In the embodiment depicted in FIG. 3A, memory device 310R is included in memory cell 200N. In some embodiments, memory device 310R is included in memory cell 200P.

As depicted in FIGS. 3A-3C, each of memory devices 310N, 310P, and 310R included in a corresponding memory cell 200N or 200P is configured to be coupled to bit line WBL responsive to signals WWL and YSEL such that a memory circuit, e.g., memory circuit 100, including memory cells 200N or 200P including memory devices 310N, 310P, or 310R is capable of realizing the benefits discussed above with respect to memory circuit 100 and memory cells 200N and 200P.

FIG. 4 is a cross-sectional view of IC device 400, in accordance with some embodiments. IC device 400 is a BEOL device positioned in an interconnect structure of an IC, e.g., memory circuit 100 discussed above.

FIG. 4 depicts IC device 400, including transistors T1 and T2 and storage node STN, and X and Z directions. IC device 400 is usable in a configuration of memory cell 200N or 200P in which instances of transistors T1 and T2 and storage node STN are usable as respective transistors W0 and W1 and storage node SNW discussed above with respect to FIGS. 2A-3C. In some embodiments, IC device 400 is usable in a configuration of memory cell 200N or 200P in which instances of transistors T1 and T2 and storage node STN are also usable as respective transistors R0 and W0 and storage node SN discussed above with respect to FIGS. 3A and 3B.

Transistor T1 includes S/D structures SD1 and SD2, a gate structure G1, an oxide layer OX1, and a channel layer CH1. Transistor T2 includes S/D structures SD3 and SD4, a gate structure G2, an oxide layer OX2, and a channel layer CH2. Storage node STN includes gate G1, S/D structure SD4, and a via structure V positioned between and electrically connecting gate G1 and S/D structure SD4.

IC device 400 includes features in addition to those depicted in FIG. 4 that are not included for the purpose of illustration, e.g., one or more dielectric layers, e.g., including silicon dioxide (SiO₂), between transistors T1 and T2 and surrounding via structure V. Front end of line (FEOL) features positioned below IC device 400 are not depicted for the purpose of illustration.

The relative positioning and dimensions of the features depicted in FIG. 4 are non-limiting examples provided for the purpose of illustration. Relative positioning and dimensions other than those depicted in FIG. 4 are within the scope of the present disclosure.

In the embodiment depicted in FIG. 4, S/D structures SD1 and SD2 and gate G1 are metal segments positioned in a first metal layer of the interconnect structure, and S/D structures SD3 and SD4 and gate G2 are metal segments positioned in a second metal layer of the interconnect structure below and adjacent to the first metal layer. In some embodiments, the second layer is not adjacent to the first layer such that one or more metal layers are positioned between the first and second metal layers. In some embodiments, via structure V includes a single via structure, more than one via structure, and/or one or more metal segments in one or more metal layers between the first and second metal layers. The metal segments and via structures include one or more of copper (Cu), silver (Ag), tungsten (W), titanium (Ti), nickel (Ni), tin (Sn), aluminum (Al), or another metal or material suitable for providing a low resistance electrical path.

Oxide layers OX1 and OX2, also referred to as gate oxide layers in some embodiments, include one or more insulating materials, e.g., SiO₂, silicon nitride (Si₃N₄), and/or one or more other suitable materials such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

Channel layers CH1 and CH2 include one or more semiconductor materials, e.g., polysilicon, oxide materials, e.g., indium oxide (In₂O₃), indium tungsten oxide (IWO), and/or one or more dopants, e.g., boron (B), phosphorous (P), arsenic (As), gallium (Ga), or other suitable materials configured to provide a conductive channel between the corresponding S/D structures SD1 and SD2 or SD3 and SD4 responsive to a charge retained on the corresponding gate G1 or G2.

By the configuration discussed above, IC device 400 is capable of being included in memory cells 200N and 200P thereby enabling the benefits discussed above with respect to memory circuit 100.

FIG. 5 is a cross-sectional view of IC device diagram 500, in accordance with some embodiments. IC device 500, also referred to as variable resistance device 500 in some embodiments, is usable as RRAM device RM discussed above with respect to FIG. 3C.

IC device 500 is a microelectronic device that includes a resistive layer L1 that extends in the X and Y (not shown) directions between electrodes E1 and E2 along the Z direction. In some embodiments, IC device 500 includes one or more additional features, e.g., conductive elements, that are not depicted in FIG. 5 for the purpose of clarity.

In a programming operation, a sufficiently large voltage difference across resistive layer L1 based on voltages V1 and V2 applied on respective electrodes E1 and E2 induces formation of a filament F1, thereby providing a current path that lowers a resistance level of resistive layer L1 compared to a level corresponding to resistive layer L1 being free from including filament F1. In a read operation, a difference between voltages V1 and V2 sufficiently small to avoid filament formation induces current flow measurable by a circuit, e.g., R/W interface 130 discussed above with respect to FIGS. 1-3C.

Resistive layer L1 is one or more layers of dielectric materials configured to receive the voltage difference. In various embodiments, resistive layer L1 includes one or more of an oxide of tungsten (W), tantalum (Ta), titanium (Ti), nickel (Ni), cobalt (Co), hafnium (Hf), ruthenium (Ru), zirconium (Zr), zinc (Zn), iron (Fe), tin (Sn), aluminum (Al), copper (Cu), silver (Ag), molybdenum (Mo), chromium (Cr), or another suitable element, a composite material including, e.g., silicon, or another material capable of having either a high resistance state (HRS) or a low resistance state (LRS) based on the absence or presence of filament F1.

In the embodiment depicted in FIG. 5, resistive layer L1 includes a single filament F1, and thereby a single current path through which current flows, in operation. In various embodiments, resistive layer L1 includes one or more filaments (not shown) in addition to filament F1, and thereby a plurality of current paths through which current flows, in operation.

In various embodiments, resistive layer L1 has a resistance value ranging from 1 kilo-ohm (kΩ) to 4 kΩ in the LRS and/or a resistance value ranging from 15 kΩ to 30 kΩ in the HRS. In various embodiments, resistive layer L1 has a first range of resistance values in the LRS and a second range of resistance values in the HRS, and a difference between a maximum value of the first range and a minimum value of the second range is greater than the maximum value of the first range multiplied by 0.05 (at least 5% greater than the maximum value of the first range).

By being included in memory circuit 100 discussed above with respect to FIGS. 1-3C, IC device 500 operates to achieve the benefits discussed above with respect to memory circuit 100.

FIGS. 6A-6F depict non-limiting examples of memory circuit 100 operating parameters, in accordance with some embodiments. The examples depicted in each of FIGS. 6A-6F correspond to memory circuit 100 including memory cells 200N including memory devices 310N discussed above with respect to FIGS. 1-3C. Operating parameters corresponding to memory circuit 100 otherwise configured, e.g., including memory cells 200P and/or memory devices 310P or 310R, are within the scope of the present disclosure.

With respect to a selected memory cell 200N, FIG. 6A represents a standby mode, FIG. 6B represents a write operation, FIG. 6C represents a read operation, FIG. 6D represents a refresh operation, FIG. 6E depicts signals RWL, WWL, YSEL, and WBL corresponding to each of FIGS. 6A-6D, and FIG. 6F depicts a write operation including R/W interface 130 and multiple instances of non-selected memory cell 200N in array 110.

In the standby mode depicted in FIGS. 6A and 6E, each of word line signals RWL and WWL, select signal YSEL, and bit line signal WBL has the low logic level, and bit line signal RBL is uncontrolled with respect to the selected memory cell 200N. In response, each of transistors R1, W1, and W0 is switched off, storage node SNW is decoupled from select line YSEL and retains a (previously applied) charge corresponding to the low logic level, and storage node SN is decoupled from bit line WBL and retains a (previously programmed) charge corresponding to the high or low logic level (not shown).

In the write mode depicted in FIGS. 6B and 6E, word line signal RWL has the low logic level, each of word line signals WWL and select signal YSEL has the high logic level, bit line signal WBL has the high or low logic level corresponding to the written data, and bit line signal RBL is uncontrolled with respect to the selected memory cell 200N. In response, transistor R1 is switched off, each of transistors W1 and W0 is switched on, storage node SNW is coupled to select line YSEL and receives a charge corresponding to the high logic level, and storage node SN is coupled to bit line WBL and receives a charge corresponding to the high or low logic level (not shown) of the written data.

In the read mode depicted in FIGS. 6C and 6E, word line signal RWL has the high logic level, each of word line signals WWL and select signal YSEL has the low logic level, and bit line signal WBL is uncontrolled with respect to the selected memory cell 200N. In response, transistor R1 is switched on, each of transistors W1 and W0 is switched off, storage node SNW is decoupled from select line YSEL and retains a (previously applied) charge corresponding to the low logic level, storage node SN is decoupled from bit line WBL and retains the charge corresponding to the high or low logic level (not shown) of the written data, and bit line signal RBL has the high or low logic level corresponding to the previously written data based on the charge retained on storage node SN.

In the refresh mode depicted in FIGS. 6D and 6E, each of word line signals RWL and WWL and select signal YSEL has the high logic level. In response, each of transistors R1, W1, and W0 is switched on, storage node SNW is coupled to select line YSEL and receives a charge corresponding to the high logic level, each of bit line signals RBL and WBL has the high or low logic level corresponding to the previously written data based on the charge retained on storage node SN, storage node SN is coupled to bit line WBL and receives the charge corresponding to the previously written data.

As depicted in FIG. 6F (lines/signals not labeled for clarity), the write mode of a selected memory cell 200N (labeled) includes the signals depicted in FIGS. 6B and 6E. A second (non-selected) instance of memory cell 200N in the same row as the selected memory cell 200N also receives word line signal WWL having the high logic level. In response to the corresponding select signal YSEL having the low logic level, transistor W0 of the non-selected memory cell 200N is switched off and storage node SN is decoupled from bit line WBL such that a charge retained on storage node SN is not disturbed in response to word line signal WWL having the high logic level.

FIGS. 6A-6F thereby provide a non-limiting illustration of memory circuit 100 operation in which a memory device of a non-selected memory cell 200N or 200P is not disturbed in response to word line signal WWL having a logic level configured to cause data to be written to a selected memory cell 200N or 200P in the same row as the non-selected memory cell 200N or 200P.

In some embodiments, memory circuit 100 is otherwise configured such that a memory device of a non-selected memory cell 200N or 200P is not disturbed in response to word line signal WWL having a logic level configured to cause data to be written to a selected memory cell 200N or 200P in the same row as the non-selected memory cell 200N or 200P, e.g., based on memory cells 200P receiving signals having logic levels opposite those depicted in FIGS. 6A-6F, or non-selected memory cells 200N or 200P including memory devices 310R including terminals that are not coupled to bit lines WBL in response to word line signal WWL having the logic level configured to cause data to be written to a selected memory cell 200N or 200P.

FIG. 7 is a flowchart of method 700 of operating a memory circuit, in accordance with some embodiments. Method 700 is usable with a memory circuit, e.g., memory circuit 100 including instances of memory cell 200N or 200P, discussed above with respect to FIGS. 1-6F. In some embodiments, the operations of method 700 are a subset of operations of a method of operating a CIM or NMC circuit.

The sequence in which the operations of method 700 are depicted in FIG. 7 is for illustration only; the operations of method 700 are capable of being executed in sequences that differ from that depicted in FIG. 7. In some embodiments, operations in addition to those depicted in FIG. 7 are performed before, between, during, and/or after the operations depicted in FIG. 7.

At operation 710, in some embodiments, a first memory cell is operated in a standby mode by a memory circuit, e.g., memory circuit 100 discussed above with respect to FIGS. 1-6F. In some embodiments, operating the first memory cell in standby mode includes operating memory cell 200N or 200P, discussed above with respect to FIGS. 2A-6F.

In some embodiments, performing a standby operation includes applying a charge to a storage node between a S/D terminal of a first transistor and a gate of a second transistor of the first memory cell, the charge configured to switch off the second transistor and decouple a memory device of the first memory cell from a first bit line of the memory circuit.

In some embodiments, operating the first memory cell in standby mode includes performing a standby operation as discussed above with respect to FIGS. 6A and 6E.

At operation 720, a data bit is written to the first memory cell using a word line signal and a select signal, e.g., writing a data bit to memory cell 200N or 200P using word line signal WWL and select signal YSEL discussed above with respect to FIGS. 2A-6F.

Writing the data bit to the first memory cell includes the memory circuit outputting a word line signal having a first logic level to a gate of the first transistor of the first memory cell, the first transistor including a first S/D terminal coupled to a first select line in addition to the second S/D terminal coupled to the storage node of the first memory cell, outputting a first select signal having the first logic level to the first select line, receiving, from the first transistor, a first charge corresponding to the first logic level of the first select signal at the storage node and the gate of a second transistor of the first memory cell, using the second transistor to couple the memory device of the first memory cell to the first bit line in response to receiving the first charge, and outputting the data bit to the first bit line.

In some embodiments, writing the data bit to the first memory cell includes performing a write operation as discussed above with respect to FIGS. 6B and 6E.

In some embodiments, using the second transistor to couple the memory device of the first memory cell to the first bit line includes coupling one of memory devices 310N, 310P, or 310R to bit line WBL as discussed above with respect to FIGS. 3A-3C.

In some embodiments, writing the data bit to the first memory cell includes outputting the word line signal having the first logic level to a gate of a first transistor of a second memory cell, the first transistor comprising a first S/D terminal coupled to a second select line and a second S/D terminal coupled to a storage node of the second memory cell, outputting a second select signal having a second logic level to the second select line, receiving, from the first transistor of the second memory cell, a second charge corresponding to the second logic level of the second select signal at the storage node of the second memory cell and a gate of a second transistor of the second memory cell coupled to the storage node of the second memory cell, and using the second transistor of the second memory cell to decouple a memory device of the second memory cell from a second bit line in response to receiving the second charge.

In some embodiments, writing the data bit to the first memory cell includes performing a write operation as discussed above with respect to FIG. 6F.

At operation 730, in some embodiments, the data bit is read from the first memory cell. In some embodiments, reading the data bit from the first memory cell includes reading the data bit from memory cell 200N or 200P, discussed above with respect to FIGS. 2A-6F.

In some embodiments, reading the data bit from the first memory cell includes performing a read operation as discussed above with respect to FIGS. 6C and 6E.

At operation 740, in some embodiments, a refresh operation is performed on the first memory cell. In some embodiments, performing the refresh operation on the first memory cell includes performing the refresh operation on memory cell 200N or 200P, discussed above with respect to FIGS. 2A-6F.

In some embodiments, performing the refresh operation on the first memory cell includes performing the refresh operation as discussed above with respect to FIGS. 6D and 6E.

By executing some or all of the operations of method 700, a memory circuit is capable of selectively coupling memory devices to corresponding bit lines in response to combinations of word line and select signals, whereby half-selected disturb conditions are avoided on non-selected memory cells, thereby achieving the benefits discussed above with respect to memory circuit 100 and memory cells 200N and 200P.

FIG. 8 is a flowchart of method 800 of manufacturing a memory circuit, in accordance with some embodiments. Method 800 is operable to form memory circuit 100 including memory cells 200N or 200P discussed above with respect to FIGS. 1-6F.

In some embodiments, the operations of method 800 are performed in the order depicted in FIG. 8. In some embodiments, the operations of method 800 are performed in an order other than the order of FIG. 8. In some embodiments, one or more additional operations are performed before, during, between, and/or after the operations of method 800.

In some embodiments, one or more operations of method 800 are a subset of operations of a method of forming an IC and/or IC package including one or more memory arrays, e.g., a CIM or NMC IC.

At operation 810, a plurality of FEOL devices is constructed on a semiconductor substrate. Constructing the plurality of FEOL devices includes forming one or more devices, e.g., transistors including S/D structures in active areas of the semiconductor substrate, gate structures on and/or in the active areas, and electrical connections between the devices in accordance with an IC design.

Constructing the plurality of FEOL devices includes performing a first plurality of manufacturing operations, e.g., one or more of a lithography, diffusion, deposition, etching, planarizing, or other operation suitable for building a resistive, magnetic, or other material layer, a dielectric layer, and/or a gate structure adjacent to S/D structures and overlying or otherwise being proximate to an active area of the semiconductor substrate.

At operation 820, an array of memory cells is constructed in an interconnect structure, each memory cell including a first transistor including a S/D terminal coupled to a storage node and a second transistor coupled between a memory device and a bit line and including a gate coupled to the storage node. Constructing the array of memory cells includes constructing array 110 of memory cells 200N or 200P of memory circuit 100 discussed above with respect to FIGS. 1-6F.

In some embodiments, constructing the array of memory cells includes constructing the memory cells including storage node STN discussed above with respect to FIG. 4.

In some embodiments, constructing the array of memory cells includes constructing the memory cells including gain-cell or RRAM memory devices, e.g., memory devices 310N, 310P, or 310R discussed above with respect to FIGS. 3A-5.

In some embodiments, constructing the array of memory cells includes performing one or more BEOL operations including performing a second plurality of manufacturing operations, e.g., one or more of a lithography, diffusion, deposition, etching, planarizing, or other operation suitable for building metal segments, oxide and channel layers, resistive or other material layers, dielectric layers, and/or gate structures adjacent to S/D structures and overlying or otherwise being proximate to the plurality of FEOL devices.

At operation 730, in some embodiments, electrical connections to the array of memory cells are formed. Forming the electrical connections includes performing one or more etching and deposition processes by which one or more metal lines are configured in accordance with one or more masks. Performing a deposition process includes depositing one or more conductive materials, e.g., one or more of Cu, Ag, W, Ti, Ni, Sn, Al or another metal or suitable material, e.g., polysilicon.

In some embodiments, forming the electrical connections includes forming one or more of word lines WWL1-WWL4, word lines RWL1-RWL4, select lines YSEL1-YSEL4, bit lines WBL1-WBL4, or bit lines RBL1-RBL4 accordance with the embodiments discussed above with respect to FIGS. 1-6F.

By performing some or all of the operations of method 800, an IC device is manufactured including a memory circuit including memory cells capable of selectively coupling memory devices to corresponding bit lines in response to combinations of word line and select signals, whereby half-selected disturb conditions are avoided on non-selected memory cells, thereby achieving the benefits discussed above with respect to memory circuit 100 and memory cells 200N and 200P.

In some embodiments, an IC device includes a first transistor including a first S/D terminal coupled to a first select line, a second S/D terminal, and a gate coupled to a first word line, a second transistor including a first S/D terminal coupled to a first bit line, a second S/D terminal, and a gate, a first memory device coupled to the second S/D terminal of the second transistor, and a first storage node including the second S/D terminal of the first transistor and the gate of the second transistor. In some embodiments, each of the first and second S/D terminals and the gate of each of the first and second transistors includes a metal segment of an interconnect structure. In some embodiments, the first storage node includes a via structure positioned between and electrically connecting the second S/D terminal of the first transistor and the gate of the second transistor. In some embodiments, the first memory device includes a third transistor including a first S/D terminal coupled to a second bit line, a second S/D terminal, and a gate coupled to a second word line, and a fourth transistor including a first S/D terminal coupled to the second S/D terminal of the third transistor, a second S/D terminal coupled to a power distribution path, and a gate coupled to the second S/D terminal of the second transistor, and a second storage node of the IC device includes the second S/D terminal of the second transistor and the gate of the fourth transistor. In some embodiments, each of the first through fourth transistors includes an n-type transistor, and the power distribution path includes a ground path. In some embodiments, each of the first through fourth transistors includes a p-type transistor, and the power distribution path includes a power supply distribution path. In some embodiments, each of the first and second S/D terminals and the gate of each of the first through fourth transistors includes a metal segment of an interconnect structure. In some embodiments, the IC device includes a third transistor including a first S/D terminal coupled to a second select line, a second S/D terminal, and a gate coupled to the first word line, a fourth transistor including a first S/D terminal coupled to a second bit line, a second S/D terminal, and a gate, a second memory device coupled to the second S/D terminal of the fourth transistor, and a second storage node including the second S/D terminal of the third transistor and the gate of the fourth transistor. In some embodiments, the IC device includes a third transistor including a first S/D terminal coupled to the first select line, a second S/D terminal, and a gate coupled to a second word line, a fourth transistor including a first S/D terminal coupled to the first bit line, a second S/D terminal, and a gate, a second memory device coupled to the second S/D terminal of the fourth transistor, and a second storage node including the second S/D terminal of the third transistor and the gate of the fourth transistor. In some embodiments, the first memory device includes an RRAM device including a first terminal coupled to the second S/D terminal of the second transistor and a second terminal coupled to a signal line.

In some embodiments, a memory circuit includes an array of memory cells arranged in rows and columns, a row decoder coupled to a plurality of first word lines corresponding to the rows of memory cells, and a R/W interface coupled to pluralities of select and first bit lines corresponding to the columns of memory cells, wherein each memory cell of the array includes a first transistor including a first S/D terminal coupled to a corresponding select line of the plurality of select lines, a second S/D terminal, and a gate coupled to a corresponding first word line of the plurality of first word lines, a second transistor including a first S/D terminal coupled to a corresponding first bit line of the plurality of first bit lines, a second S/D terminal, and a gate, a memory device coupled to the second S/D terminal of the second transistor, and a first storage node including the second S/D terminal of the first transistor and the gate of the second transistor. In some embodiments, the row decoder is further coupled to a plurality of second word lines corresponding to the rows of memory cells, the R/W interface is further coupled to a plurality of second bit lines corresponding to the columns of memory cells, the memory device of each memory cell of the array includes a third transistor including a first S/D terminal coupled to a corresponding second bit line of the plurality of second bit lines, a second S/D terminal, and a gate coupled to a corresponding second word line of the plurality of second word lines, and a fourth transistor including a first S/D terminal coupled to the second S/D terminal of the third transistor, a second S/D terminal coupled to a power distribution path of the memory circuit, and a gate coupled to the second S/D terminal of the second transistor, and a second storage node of each memory cell of the array includes the corresponding second S/D terminal of the second transistor and gate of the fourth transistor. In some embodiments, each memory cell of the array includes each of the first through fourth transistors including an n-type transistor, and the power distribution path includes a ground path. In some embodiments, each memory cell of the array includes each of the first through fourth transistors comprising a p-type transistor, and the power distribution path includes a power supply distribution path. In some embodiments, the memory circuit includes an interconnect structure including the first storage node of each memory cell of the array. In some embodiments, the R/W interface is further coupled to a plurality of signal lines corresponding to the columns of memory cells, and the memory device of each memory cell of the array includes an RRAM device including a first terminal coupled to the second S/D terminal of the second transistor and a second terminal coupled to a corresponding signal line of the plurality of signal lines. In some embodiments, the R/W interface includes a column decoder configured to output a plurality of select signals to the plurality of select lines responsive to a received address.

In some embodiments, a method of operating a memory circuit includes writing a data bit to a first memory cell by outputting a word line signal having a first logic level to a gate of a first transistor of the first memory cell, the first transistor including a first S/D terminal coupled to a first select line and a second S/D terminal coupled to a storage node of the first memory cell, outputting a first select signal having the first logic level to the first select line, receiving, from the first transistor, a first charge corresponding to the first logic level of the first select signal at the storage node and a gate of a second transistor of the first memory cell coupled to the storage node, in response to receiving the first charge, using the second transistor to couple a memory device of the first memory cell to a first bit line, and outputting the data bit to the first bit line. In some embodiments, writing the data bit to the first memory cell includes outputting the word line signal having the first logic level to a gate of a first transistor of a second memory cell, the first transistor including a first S/D terminal coupled to a second select line and a second S/D terminal coupled to a storage node of the second memory cell, outputting a second select signal having a second logic level to the second select line, receiving, from the first transistor of the second memory cell, a second charge corresponding to the second logic level of the second select signal at the storage node of the second memory cell and a gate of a second transistor of the second memory cell coupled to the storage node of the second memory cell, and in response to receiving the second charge, using the second transistor of the second memory cell to decouple a memory device of the second memory cell from a second bit line. In some embodiments, using the second transistor to couple the memory device of the memory cell to the first bit line includes using the second transistor to couple a storage node of a gain-cell device to the first bit line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
a first transistor comprising:
a first source/drain (S/D) terminal coupled to a first select line;
a second S/D terminal; and
a gate coupled to a first word line;
a second transistor comprising:
a first S/D terminal coupled to a first bit line;
a second S/D terminal; and
a gate;
a first memory device coupled to the second S/D terminal of the second transistor; and
a first storage node comprising the second S/D terminal of the first transistor and the gate of the second transistor.

2. The IC device of claim 1, wherein
each of the first and second S/D terminals and the gate of each of the first and second transistors comprises a metal segment of an interconnect structure.

3. The IC device of claim 2, wherein the first storage node further comprises:
a via structure positioned between and electrically connecting the second S/D terminal of the first transistor and the gate of the second transistor.

4. The IC device of claim 1, wherein
the first memory device comprises:
a third transistor comprising:
a first S/D terminal coupled to a second bit line;
a second S/D terminal; and
a gate coupled to a second word line; and
a fourth transistor comprising:
a first S/D terminal coupled to the second S/D terminal of the third transistor;
a second S/D terminal coupled to a power distribution path; and
a gate coupled to the second S/D terminal of the second transistor, and
a second storage node of the IC device comprises the second S/D terminal of the second transistor and the gate of the fourth transistor.

5. The IC device of claim 4, wherein
each of the first through fourth transistors comprises an n-type transistor, and
the power distribution path comprises a ground path.

6. The IC device of claim 4, wherein
each of the first through fourth transistors comprises a p-type transistor, and
the power distribution path comprises a power supply distribution path.

7. The IC device of claim 4, wherein
each of the first and second S/D terminals and the gate of each of the first through fourth transistors comprises a metal segment of an interconnect structure.

8. The IC device of claim 1, further comprising:
a third transistor comprising:
a first S/D terminal coupled to a second select line;
a second S/D terminal; and
a gate coupled to the first word line;
a fourth transistor comprising:
a first S/D terminal coupled to a second bit line;
a second S/D terminal; and
a gate;
a second memory device coupled to the second S/D terminal of the fourth transistor; and
a second storage node comprising the second S/D terminal of the third transistor and the gate of the fourth transistor.

9. The IC device of claim 1, further comprising:
a third transistor comprising:
a first S/D terminal coupled to the first select line;
a second S/D terminal; and
a gate coupled to a second word line;
a fourth transistor comprising:
a first S/D terminal coupled to the first bit line;
a second S/D terminal; and
a gate;
a second memory device coupled to the second S/D terminal of the fourth transistor; and
a second storage node comprising the second S/D terminal of the third transistor and the gate of the fourth transistor.

10. The IC device of claim 1, wherein the first memory device comprises a resistive random-access memory (RRAM) device comprising:
a first terminal coupled to the second S/D terminal of the second transistor; and
a second terminal coupled to a signal line.

11. A memory circuit comprising:
an array of memory cells arranged in rows and columns;
a row decoder coupled to a plurality of first word lines corresponding to the rows of memory cells; and
a read/write (R/W) interface coupled to pluralities of select and first bit lines corresponding to the columns of memory cells,
wherein each memory cell of the array comprises:
a first transistor comprising:
a first source/drain (S/D) terminal coupled to a corresponding select line of the plurality of select lines;
a second S/D terminal; and
a gate coupled to a corresponding first word line of the plurality of first word lines;
a second transistor comprising:
a first S/D terminal coupled to a corresponding first bit line of the plurality of first bit lines;
a second S/D terminal; and
a gate;
a memory device coupled to the second S/D terminal of the second transistor; and
a first storage node comprising the second S/D terminal of the first transistor and the gate of the second transistor.

12. The memory circuit of claim 11, wherein
the row decoder is further coupled to a plurality of second word lines corresponding to the rows of memory cells,
the R/W interface is further coupled to a plurality of second bit lines corresponding to the columns of memory cells,
the memory device of each memory cell of the array comprises:
a third transistor comprising:
a first S/D terminal coupled to a corresponding second bit line of the plurality of second bit lines;
a second S/D terminal; and
a gate coupled to a corresponding second word line of the plurality of second word lines; and
a fourth transistor comprising:
a first S/D terminal coupled to the second S/D terminal of the third transistor;
a second S/D terminal coupled to a power distribution path of the memory circuit; and
a gate coupled to the second S/D terminal of the second transistor, and
a second storage node of each memory cell of the array comprises the corresponding second S/D terminal of the second transistor and gate of the fourth transistor.

13. The memory circuit of claim 12, wherein
each memory cell of the array comprises each of the first through fourth transistors comprising an n-type transistor, and
the power distribution path comprises a ground path.

14. The memory circuit of claim 12, wherein
each memory cell of the array comprises each of the first through fourth transistors comprising a p-type transistor, and
the power distribution path comprises a power supply distribution path.

15. The memory circuit of claim 11, further comprising:
an interconnect structure comprising the first storage node of each memory cell of the array.

16. The memory circuit of claim 11, wherein
the R/W interface is further coupled to a plurality of signal lines corresponding to the columns of memory cells, and
the memory device of each memory cell of the array comprises:
a resistive random-access memory (RRAM) device comprising:
a first terminal coupled to the second S/D terminal of the second transistor; and
a second terminal coupled to a corresponding signal line of the plurality of signal lines.

17. The memory circuit of claim 11, wherein
the R/W interface comprises a column decoder configured to output a plurality of select signals to the plurality of select lines responsive to a received address.

18. A method of operating a memory circuit, the method comprising:
writing a data bit to a first memory cell by:
outputting a word line signal having a first logic level to a gate of a first transistor of the first memory cell, the first transistor comprising a first source/drain (S/D) terminal coupled to a first select line and a second S/D terminal coupled to a storage node of the first memory cell;
outputting a first select signal having the first logic level to the first select line;
receiving, from the first transistor, a first charge corresponding to the first logic level of the first select signal at the storage node and a gate of a second transistor of the first memory cell coupled to the storage node;
in response to the receiving the first charge, using the second transistor to couple a memory device of the first memory cell to a first bit line; and
outputting the data bit to the first bit line.

19. The method of claim 18, wherein the writing the data bit to the first memory cell further comprises:
outputting the word line signal having the first logic level to a gate of a first transistor of a second memory cell, the first transistor comprising a first S/D terminal coupled to a second select line and a second S/D terminal coupled to a storage node of the second memory cell;
outputting a second select signal having a second logic level to the second select line;
receiving, from the first transistor of the second memory cell, a second charge corresponding to the second logic level of the second select signal at the storage node of the second memory cell and a gate of a second transistor of the second memory cell coupled to the storage node of the second memory cell; and
in response to the receiving the second charge, using the second transistor of the second memory cell to decouple a memory device of the second memory cell from a second bit line.

20. The method of claim 18, wherein
the using the second transistor to couple the memory device of the memory cell to the first bit line comprises using the second transistor to couple a storage node of a gain-cell device to the first bit line.
